(19) United States
(12) Patent Application Publication
(10) Pub. No.: US 2024/0332328 A1
(43) Pub. Date: Oct. 3, 2024

(54) OPTICAL SENSOR PACKAGE WITH LIGHT SHIELDING MATERIAL

(71) Applicant: STMicroelectronics International N.V., GEneva (CH)

(72) Inventors: Hui-Tzu WANG, Zhubei (TW); David GANI, Choa Chu Kang (SG); Yiying KUO, Taoyuan (TW)

(73) Assignee: STMicroelectronics International N.V., Geneva (CH)

(21) Appl. No.: 18/607,215

(22) Filed: Mar. 15, 2024

Related U.S. Application Data
(60) Provisional application No. 63/492,987, filed on Mar. 29, 2023.

(51) Int. Cl. H01L 27/146; H01L 23/00

(52) U.S. Cl. CPC H01L 27/14623; H01L 24/13; H01L 24/14; H01L 27/14618; H01L 27/14685; H01L 2224/13021; H01L 2224/13024; H01L 2224/13082; H01L 2224/14051; H01L 2224/14183

(57) ABSTRACT

The present disclosure is directed to an optical sensor package with light shielding material covering five sides. The optical sensor package includes a transparent layer, a substrate layer, sensor elements between the transparent layer and the substrate layer, a solder mask on the side of the substrate layer opposite the transparent layer, and layer of molding material covering five sides of the optical sensor package. The solder mask and layer of molding material prevent light from entering the sides of the optical sensor package or from traveling through the substrate layer and reflecting toward the sensor elements.

### BACKGROUND

### Technical Field

The present disclosure relates to a light shielding packaging for an optical sensing device.

### Description of the Related Art

Optical sensors packages are devices capable of converting light rays into electronic signals. Typically, optical sensor packages are a cavity type package with a glass layer on a Bismaleimide Triazine (BT) substrate and a cavity or space between the glass layer and a semiconductor chip on the BT substrate. In operation, light entering the optical sensor package through the glass layer is detected by the semiconductor chip, whereas light directed at the BT substrate on the sides of the cavity is blocked from entering the cavity and from being detected by the semiconductor chip. This reduces light interference, which optimizes performance of the optical sensor.

However, known optical sensor packages suffer from a key disadvantage. For example, the presence of the cavity in the package results in packages with a larger size, which is counter to general market trends towards smaller electronic devices. In other words, in modern electronic devices, space is at a premium, which makes larger packages significantly less preferable. In some products, low profile optical sensor packages have form factor of an electronic device and thus larger packages may not be usable.

### BRIEF SUMMARY

The present disclosure is directed to an optical sensor package with light shielding material covering five sides. More specifically, the optical sensor package includes a transparent layer on a substrate layer with sensor elements between the transparent layer and the substrate layer. While an outer surface of the transparent layer remains uncovered, each of the five other surfaces of the optical sensor package are covered in a layer of light shielding material. The transparent layer may be glass. The light shielding material may include a solder mask and molding material. The present disclosure further includes a first plurality of solder balls on the substrate layer and a second plurality of solder balls coupled to the first plurality of solder balls.

The layer of light shielding material on the sidewalls of the optical sensor package prevents light from entering the optical sensor package through the sidewalls of the transparent layer and being detected by the sensor elements. Additionally, the layer of light shielding material on the face of the optical sensor package opposite the uncovered face prevents light from traveling through the substrate layer and reflecting toward the sensor elements. When the sensor elements detect light from the sidewalls or light reflecting through the substrate layer, unnecessary signal noise is generated which affects performance of the optical sensor package.

The present disclosure overcomes the drawbacks of the prior art. Since the sidewalls of the transparent or glass layer are covered by the layer of light shielding material, a cavity within the package can be eliminated. Thus, the optical sensor package of the present disclosure can retain a smaller size, while preventing light from entering through the sidewalls and substrate layer of the optical sensor package.

### BRIEF DESCRIPTION OF THE SEVERAL VIEWS OF THE DRAWINGS

For a better understanding of the present disclosure, one or more embodiments will now be described by way of example only, with reference to the accompanying drawings. In the drawings, identical reference numbers identify similar elements or acts. In some figures, the structures are drawn exactly to scale. In other figures, the sizes and relative positions of elements in the drawings are not necessarily drawn to scale. For example, the sizes, shapes of various elements and angles may be enlarged and positioned in the figures to improve drawing legibility.

FIG. 1 is a cross-sectional view of an optical sensor package with a layer of molding material covering five sides.

FIGS. 2A-2G are cross-sectional views of an embodiment of a method of assembling the optical sensor package in FIG. 1.

### DETAILED DESCRIPTION

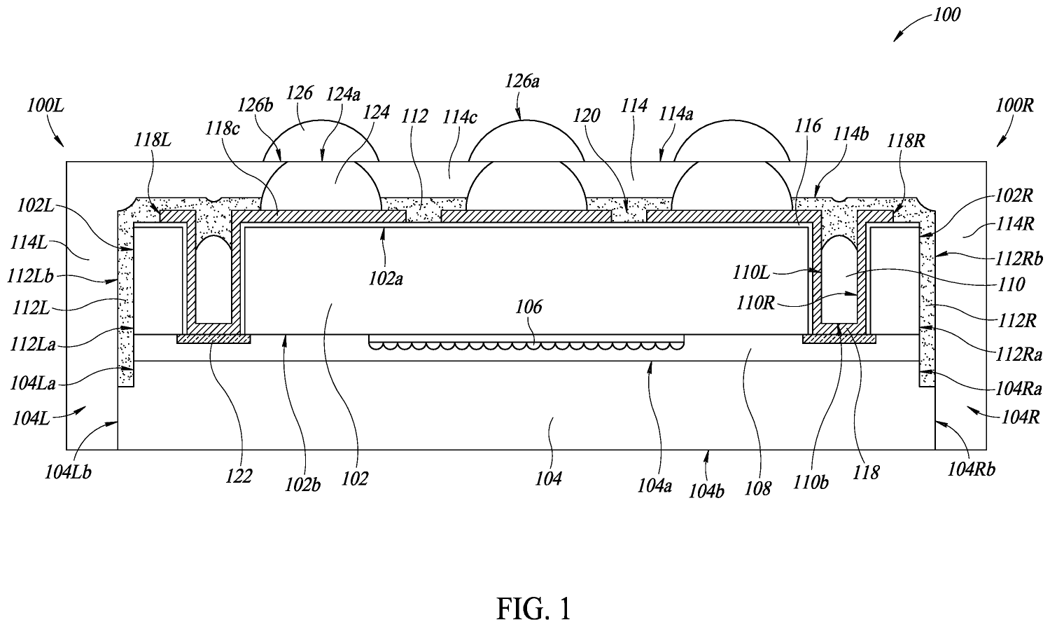

FIG. 1 is an electronic device 100, which may be an optical sensor package, including a substrate layer 102 with a first surface 102a and a second surface 102b. A transparent layer 104 with a first surface 104a and a second surface 104b is attached to the substrate layer 102 by a glue layer 108. Sensor elements 106 may extend into the glue layer 108 or may be within the substrate layer 102. In some embodiments, portions of the sensor elements 106 are positioned between the second surface 102b of the substrate layer 102 and the first surface 104a of the transparent layer 104.

A plurality of through silicon vias (TSVs) 110 extend from the first surface 102a to the second surface 102b of the substrate layer 102. A solder mask 112 covers the first surface 102a of the substrate layer 102 and a portion of a first sidewall 100L and a second sidewall 100R of the electronic device 100. A layer of molding material 114 covers the solder mask 112 over the first surface 102a of the substrate layer 102. The layer of molding material 114 further covers the first and second sidewall, 100L and 100R, of the electronic device 100. Although not shown in the cross-sectional view, all four lateral sidewalls of the electronic device 100 are covered by the layer of molding material 114. The four lateral sidewalls include the first and second sidewall, 100L and 100R.

The substrate layer 102 extends in a first direction from a first surface 102a to a second surface 102b. The substrate layer 102 extends in a second direction from a first sidewall 102L to a second sidewall 102R, the second direction being transverse to the first direction. The substrate layer 102 may be silicon.

The transparent layer 104 extends in the first direction from a first surface 104a to a second surface 104b. The transparent layer 104 extends in the second direction from a first sidewall 104L to a second sidewall 104R. The first sidewall 104L includes a first portion 104La and a second portion 104Lb, which are not coplanar. The second sidewall 104R includes a first portion 104Ra and a second portion 104Rb, which are not coplanar. The distance between the first portion 104La of the first sidewall 104L and the first portion 104Ra of the second sidewall 104R is smaller than the distance between distance between the second portion 104Lb of the first sidewall 104L and the second portion 104Rb of the second sidewall 104R. The transparent layer 104 may be glass.

The sensor elements 106 may be used for light sensing or image sensing in some embodiments.

The TSVs 110 extend through the substrate layer 102. Although only two of the TSVs 110 are shown in FIG. 1, embodiments may include more or fewer TSVs 110. According to embodiments, each TSV 110 includes a first internal sidewall 110L and a second internal sidewall 110R. The first internal sidewall 110L and the second internal sidewall 110R may be the same surface, for example, when each TSV is cylindrical in shape. Each TSV 110 includes an end surface 110b, which is closest to or at the second surface 102b of the substrate layer.

A dielectric layer 116, which may be an oxide layer, covers the first internal sidewall 110L and the second internal sidewall 110R of each TSV 110. The dielectric layer 116 covers the first surface 102a of the substrate layer 102. The dielectric layer 116 may extend between multiple TSVs 110. According to an embodiment, the dielectric layer 116 completely covers the first surface 102a of the substrate layer 102 and the internal sidewalls, 110R and 110L, of each TSV 110. The dielectric layer 116 may not cover the end surface 110b of each TSV 110.

A redistribution layer 118, which includes conductive and dielectric components, lines the internal sidewalls 110L and 110R of each TSV 110. The redistribution layer 118 also covers the end surface 110b of each TSV 110. In some embodiments, the redistribution layer 118 completely covers the end surface 110b. The redistribution layer 118 extends onto the dielectric layer 116 that is covering the first surface 102a of the substrate layer 102, but only partially covers the dielectric layer 116. That is, the redistribution layer 118 does not extend between adjacent TSVs 110. A plurality of portions of the dielectric layer 116 between adjacent TSVs 110 remain uncovered by the redistribution layer 118, forming a plurality of gaps 120 in the redistribution layer 118. Although two gaps 120 are shown in FIG. 1, embodiments may include more or fewer gaps 120. The redistribution layer 118 includes contact areas 118c, which cover the first surface 102a of the substrate layer 102. The contact areas 118c may belong to portions of the redistribution layer 116 which also line the internal sidewalls, 110L and 110R, of the TSVs 110. The contact areas 118c, alternatively, may not belong to portions of the redistribution layer 118 which line the internal sidewalls, 110L and 110R, of the TSVs 110. That is, the contact areas 118c may be surrounded by gaps 120 in the redistribution layer 118, such that the contact areas 118c are not in physical contact with the TSVs 110.

The redistribution layer 118 does not extend to the sidewalls 100L and 100R of the electronic device 100. That is, a first sidewall 118L and a second sidewall 118R of the redistribution layer 118 are not coplanar with the first sidewall 102L and the second sidewall 102R, respectively, of the substrate layer 102.

A first plurality of solder balls 124 are coupled to the contact areas 118c. Each of the plurality of solder balls 124 includes a flat surface 124a which may be parallel to the contact areas 118c.

A plurality of contacts 122, which include conductive components, are embedded, or otherwise formed, in the glue layer 108 and are coplanar with the second surface 102b of the substrate layer 102. The contacts 122 are coupled to the redistribution layer 118 on the internal surfaces of the TSVs 110. The contacts 122 may be wider in the second direction than each TSV 110.

The solder mask 112 may entirely cover the first surface 102a of the substrate layer 102. The solder mask 112 prevents light from traveling through the substrate layer 102 and reflecting toward the sensor elements 106, generating signal noise. The solder mask 112 may partially fill the TSVs 110. Each TSV 110 is at least partially filled with air or includes an unfilled gap.

The solder mask 112 includes a first sidewall 112L, which has an inner surface 112La and an outer surface 112Lb. The inner surface 112La is coplanar with the first portion 104La of the first sidewall 104L of the transparent layer 104. The outer surface 112Lb is coplanar with the second portion 104Lb of the first sidewall 104L of the transparent layer 104. The solder mask 112 includes a second sidewall 112R, which has an inner surface 112Ra and an outer surface 112Rb. The inner surface 112Ra is coplanar with the first portion 104Ra of the second sidewall 104R of the transparent layer 104. The outer surface 112Rb is coplanar with the second portion 104Rb of the second sidewall 104R of the transparent layer 104. The first sidewall 112L covers the entire first sidewall 102L of the substrate layer 102 and a portion of the first sidewall 104L of the transparent layer 104. The second sidewall 112R covers the entire second sidewall 102R of the substrate layer 102 and a portion of the second sidewall 104R of the transparent layer 104.

A layer of molding material 114 covers the electronic device 100 on five sides. That is, the layer of molding material 114 covers each of the sidewalls of the electronic device 100 including the first sidewall 100L and the second sidewall 100R. A first sidewall 114L of the layer of molding material 114 covers both the first sidewall 112L of the solder mask 112 and the second portion 104Lb of the first sidewall 104L of the transparent layer 104. A second sidewall 114R of the layer of molding material 114 covers both the second sidewall 112R of the solder mask 112 and the second portion 104Rb of the second sidewall 104R of the transparent layer 104. The first sidewall 114L of the layer of molding material 114 may be approximately 200 micrometers in thickness.

A first region 114c of the layer of molding material 114 covers the solder mask 112. A first, outer surface 114a of the first region 114c of the layer of molding material 114 is coplanar with the flat surfaces 124a of the first plurality of solder balls 124. The first region 114c of the layer of molding material 114 may be approximately 100 micrometers in thickness.

A second plurality of solder balls 126 are coupled to the first plurality of solder balls 124. The second plurality of solder balls 126 include a first, rounded surface 126a and a second, flat surface 126b. The second surfaces 126b of the second plurality of solder balls 126 are coupled to the flat surfaces 124a of the first plurality of solder balls 124. The second surfaces 126b of the second plurality of solder balls 126 have a larger circumference than the circumferences of the flat surfaces 124a of the first plurality of solder balls 124. Portions of the second surfaces 126b of the second plurality of solder balls 126 are on the first surface 114a of the first region 114c of the layer of molding material 114.

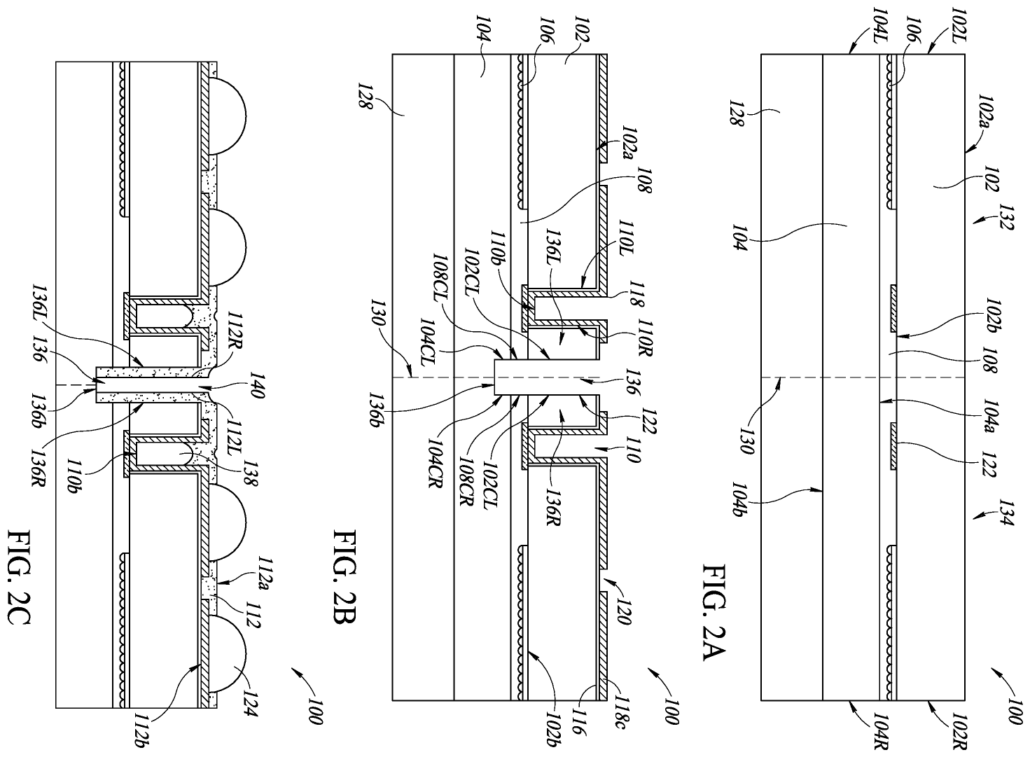

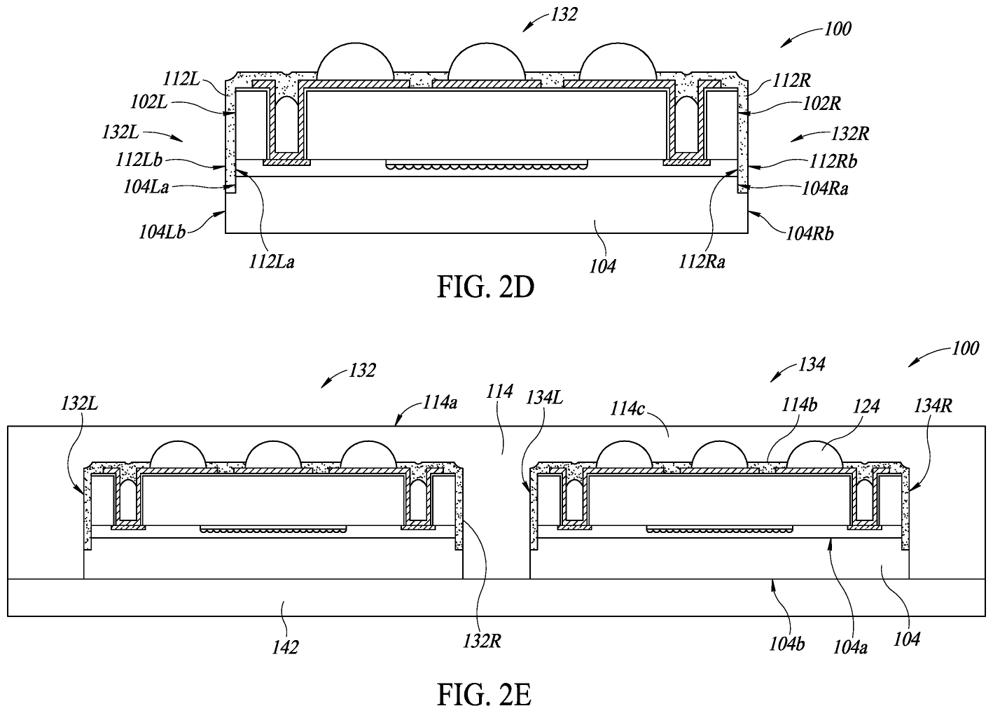

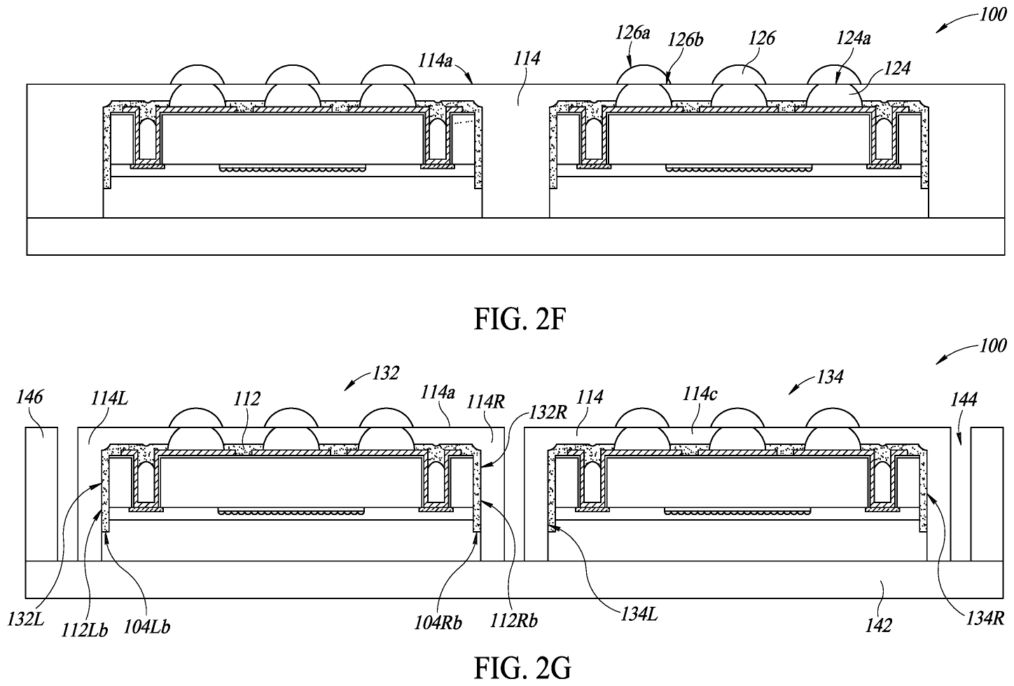

FIG. 2 is a method of assembling the electronic device 100 of FIG. 1. The method begins in FIG. 2A with an electronic device 100. The electronic device 100 includes: a substrate layer 102 with a first surface 102a and second surface 102b and a first sidewall 102L and second sidewall 102R; a transparent layer 104 with a first surface 104a and second surface 104b and a first sidewall 104L and second sidewall 104R; a glue layer 108 between the second surface 102b of the substrate layer 102 and the first surface 104a of the transparent layer 104; a plurality of sensor elements 106 formed in the glue layer 108, the plurality of sensor elements 106 being contiguous with the second surface 102b of the substrate layer 102; a plurality of contacts 122, which include conductive components and are formed in the glue layer 108, the contacts 122 being contiguous with the second surface 102b of the substrate layer 102 and coplanar with the plurality of sensor elements 106; and a first carrier layer 128 on the second surface 104b of the transparent layer 104, the first carrier layer 128 possibly including glass and possibly providing support for the electronic device 100 during the manufacturing process and reducing the probability of warpage of the transparent layer 104.

The first sidewall 102L of the substrate layer 102 and the first sidewall 104L of the transparent layer 104 are coplanar. The second sidewall 102R of the substrate layer 102 and the second sidewall 104R of the transparent layer 104 are coplanar.

The substrate layer 102 may be silicon and may be in the range of 50 and 200 micrometers in thickness. The transparent layer 104 may be glass and may be in the range of 100 and 500 micrometers in thickness.

The division line 130 demarcates a distinction between two die, a first die 132 and a second die 134, which will be separated in a later singulation step. The division line 130 extends through the substrate layer 102, the glue layer 108, the transparent layer 104, and the first carrier layer 128 in a first direction.

Although not visible in FIG. 2A, since only a portion of the first die 132 and a portion of the second die 134 are included, the first die 132 includes at least two contacts 122. The second die 134 includes at least two contacts 122. Each of the contacts 122 is coplanar with each of the other contacts 122 and with the sensor elements 106 along a second direction that is transverse with the first direction. Two contacts 122 are positioned between each set of adjacent sensor elements 106. While FIG. 2A includes two die, the first die 132 and the second die 134, embodiments may include more die.

With reference to FIG. 2B, a plurality of TSVs 110 are formed in the substrate layer 102 by a process such as etching. Each TSV 110 extends from the first surface 102a to the second surface 102b of the substrate layer 102 along the first direction. Each TSV 110 is formed in line with each contact 122 along the first direction and an end surface 110b of each TSV 110 is touching each contact 122. While FIG. 2B includes two TSVs 110, embodiments may include more TSVs 110.

A dielectric layer 116, which may be an oxide layer, is formed on a first internal sidewall 110L and a second internal sidewall 110R of each TSV 110. The first internal sidewall 110L and the second internal sidewall 110R may be the same surface, for example, if each TSV 110 is cylindrical in shape. The dielectric layer 116 does not cover the end surface 110b of each TSV 110. The dielectric layer 116 is further formed over the first surface 102a of the substrate layer 102. The dielectric layer 116 may extend between adjacent TSVs 110. According to an embodiment, the dielectric layer 116 completely covers the first surface 102a of the substrate layer 102 and the first and second internal sidewalls, 110R and 110L, of each TSV 110.

A redistribution layer 118, which includes conductive and dielectric components, is formed on each first and second internal sidewall, 110R and 110L, of each TSV 110. The redistribution layer 118 is formed on the dielectric layer 116 inside each TSV 110. According to some embodiments, the redistribution layer 118 completely covers the dielectric layer 116 on each first and second internal sidewall, 110R and 110L, of each TSV 110. The redistribution layer 118 is also formed on each end surface 110b of each TSV 110. In some embodiments, the redistribution layer 118 completely covers each end surface 110b. The redistribution layer 118 on the end surface 110b is coupled to the contacts 122. The redistribution layer 118 formed on the dielectric layer 116 on the first surface 102a of the substrate layer 102 only partially covers the dielectric layer 116. That is, the redistribution layer 118 does not extend fully between adjacent TSVs 110. Rather, a plurality of gaps 120 are formed between adjacent TSVs 110 where a portion of the dielectric layer 116 remains uncovered by the redistribution layer 118. The plurality of gaps 120 may be formed by etching or by another process. The portions of the redistribution layer 118 on either side of the gaps 120 form a plurality of contact areas 118c.

The redistribution layer 114 may be metal and may be formed by processes such as photolithography or plating.

A first cavity 136 is formed between two of the plurality of TSVs 110 along the division line 130. The first cavity 136 is formed in one of the plurality of gaps 120 in the redistribution layer 118. The first cavity 136 extends along the first direction through the entire dielectric layer 116, the entire substrate layer 102, the entire glue layer, and a portion of the transparent layer 104. That is, the first cavity 136 extends along the first direction through the first surface 104a of the transparent layer 104 but does not reach the second surface 104b of the transparent layer 104. The first cavity 136 includes an end surface 136b that may be parallel to the first surface 102a of the substrate layer 102.

The first cavity 136 includes a first sidewall 136L and a second sidewall 136R. The first sidewall 136L of the first cavity 136 includes a first central sidewall 102CL of the substrate layer 102, a first central sidewall 108CL of the glue layer 108, and a first central sidewall 104CL of the transparent layer 104. Each of the first central sidewalls, 102CL, 108CL, and 104CL, are coplanar. The second sidewall 136L of the first cavity 136 includes a second central sidewall 102CR of the substrate layer 102, a second central sidewall 108CR of the glue layer 108, and a second central sidewall 104CR of the transparent layer 104. Each of the second central sidewalls, 102CR, 108CR, and 104CR, are coplanar. The first sidewall 136L and second sidewall 136R of the first cavity 136 may be perpendicular to the end surface 136b.

The first cavity 136 may be formed using a saw or by another cutting method.

With reference to FIG. 2C, a solder mask 112 is formed on the first surface 102a of the substrate layer 102 and in the first cavity 136. According to some embodiments, the first cavity 136 is completely filled with the solder mask 112. The solder mask 112 on the first surface 102a of the substrate layer 102 further covers the redistribution layer 118 and the dielectric layer 116 on the first surface 102a. A portion of each TSV 110 is filled with the solder mask 112. Each TSV 110 may include a portion that is at least partially filled with air or includes an unfilled gap 138.

Portions of the solder mask 112 that cover the contact areas 118c are removed to expose the contact areas 118c of the redistribution layer 118. The removal of portions of the solder mask 112 may be performed by etching or by another process.

A first plurality of solder balls 124 are formed on the exposed contact areas 118c of the redistribution layer 118. The first plurality of solder balls 124 include conductive components.

The first plurality of solder balls 124 may be metal.

The first carrier layer 128 is removed from the transparent layer 104 through a process such as debonding.

A second cavity 140 is formed in the solder mask 112 in the first cavity 136. The second cavity 140 along the first direction from a first, external surface 112a of the solder mask 112 to the end surface 136b of the first cavity. The second cavity 140 is narrower in the second direction than the first cavity 136. That is, the second cavity does not extend from the first sidewall 136L to the second sidewall 136R of the first cavity 136. Portions of the solder mask 112 covering the first sidewall 136L and the second sidewall 136R of the first cavity 136 are not removed during the forming of the second cavity 140. The portion of the solder mask 112 covering the second sidewall 136R of the first cavity 136 forms a first sidewall 112L of the solder mask 112. The first sidewall 112L of the solder mask 112 covers the first central sidewall 102CL of the substrate layer 102, the first central sidewall 108CL of the glue layer 108, and the first central sidewall 104CL of the transparent layer 104, as shown in FIG. 2B. The portion of the solder mask 112 covering the first sidewall 136L of the first cavity 136 forms a second sidewall 112R of the solder mask 112. The second sidewall 112R of the solder mask 112 covers the second central sidewall 102CR of the substrate layer 102, the second central sidewall 108CR of the glue layer 108, and the second central sidewall 104CR of the transparent layer 104, as shown in FIG. 2B.

The second cavity 140 may be formed with a laser. The second cavity 140 may reduce the wattage of the electronic device 100.

With reference to FIG. 2D, the first die 132 is separated from the second die 134 along the division line 130 in the first direction. FIG. 2D depicts the first die 132. The separation of the first die 132 from the second die 134 may be performed with a saw or by another cutting procedure.

The first die 132 includes a first sidewall 132L and a second sidewall 132R. The first sidewall 112L of the solder mask 112 partially covers the first sidewall 132L of the first die 132. An inner surface 112La of the first sidewall 112L of the solder mask 112 covers the first sidewall 102L of the substrate layer 102 and a first portion 104La of the first sidewall 104L of the transparent layer 104. The first sidewall 102L of the substrate layer 102 and the first portion 104La of the first sidewall 104L of the transparent layer 104 are coplanar. The first sidewall 112L of the solder mask 112 does not cover a second portion 104Lb of the first sidewall 104L of the transparent layer 104. The second portion 104Lb of the first sidewall 104L of the transparent layer 104 is coplanar with an outer surface 112Lb of the first sidewall 112L of the solder mask 112. The first sidewall 132L of the first die 132 includes the second portion 104Lb of the first sidewall 104L of the transparent layer 104 and the outer surface 112Lb of the first sidewall 112L of the solder mask 112.

The second sidewall 112R of the solder mask 112 partially covers the second sidewall 132R of the first die 132. An inner surface 112Ra of the second sidewall 112R of the solder mask 112 covers the second sidewall 102R of the substrate layer 102 and a first portion 104Ra of the second sidewall 104R of the transparent layer 104. The second sidewall 102R of the substrate layer 102 and the first portion 104Ra of the second sidewall 104R of the transparent layer 104 are coplanar. The second sidewall 112R of the solder mask 112 does not cover a second portion 104Rb of the second sidewall 104R of the transparent layer 104. The second portion 104Rb of the second sidewall 104R of the transparent layer 104 is coplanar with an outer surface 112Rb of the second sidewall 112R of the solder mask 112. The second sidewall 132R of the first die 132 includes the second portion 104Rb of the second sidewall 104R of the transparent layer 104 and the outer surface 112Rb of the second sidewall 112R of the solder mask 112.

With reference to FIG. 2E, the first die 132 and second die 134, which have been separated, are both mounted onto a second carrier layer 142. The second carrier layer 142 is in contact with the second surface 104b of the transparent layer 104. Although only the first and second die, 132 and 134, are shown in FIG. 2E, embodiments may include more die mounted to the second carrier layer 142.

A layer of molding material 114 is formed on five sides of both the first die 132 and the second die 134. The layer of molding material 114 includes a first region 114c which covers a portion of the external surface 112a of the solder mask 112 that is on the first surface 102a of the substrate layer 102. The first region 114c of the layer of molding material 114 also covers the first plurality of solder balls 124.

The layer of molding material 114 also completely covers the first sidewall 132L and the second sidewall 132R of the first die 132. The layer of molding material 114 also completely covers a first sidewall 134L and a second sidewall 134R of the second die 134. The layer of molding material 114 touches the second carrier layer 142 on each side of both the first die 132 and the second die 134.

The layer of molding material 114 may include plastic, epoxy, or another substance.

With reference to FIG. 2F, the first region 114c of the layer of molding material 114 and a portion of the first plurality of solder balls 124 are removed in a process that may include grinding. When a portion of the first plurality of solder balls 124 is removed, the first plurality of solder balls 124 are each left with a flat surface 124a that is coplanar with a first, outer surface 114a of the layer of molding material 114.

A second plurality of solder balls 126 are formed on the first plurality of solder balls 124. The second plurality of solder balls 126 each have a rounded, outer surface 126a and a flat surface 126b. The flat surfaces 126b of each of the second plurality of solder balls 126 are coupled to the flat surfaces 124a of each of the first plurality of solder balls 124. The flat surface 126b of each of the second plurality of solder balls 126 may be round and may have a circumference greater than that of the flat surfaces 124a of each of the first plurality of solder balls 124. That is, the flat surfaces 126b may be coupled to both the flat surfaces 124a of each of the first plurality of solder balls 124 and to the first surface 114a of the layer of molding material 114.

With reference to FIG. 2G, a plurality of singulation cavities 144 are formed in the layer of molding material 114. The plurality of singulation cavities 144 extend from the first surface 114a of the layer of molding material 114 to the second carrier layer 142 in the first direction. One of the plurality of singulation cavities 144 is formed between the first die 132 and the second die 134. The singulation cavity 144 between the first and second die, 132 and 134, is narrower in the second direction than the distance between the first die 132 and the second die 134. That is, the singulation cavity 144 does not extend from the second sidewall 132R of the first die 132 to the first sidewall 134L of the second die 134. Portions of the layer of molding material 114 between the first die 132 and second die 134 are not removed during the forming of the singulation cavity 144. The portion of the layer of molding material 114 covering the first sidewall 134L of the second die 134 forms a first sidewall 114L of the layer of molding material 114. The first sidewall 114L of the layer of molding material 114 covers the outer surface 112Rb of the first sidewall 112L of the solder mask 112 on the second die 134. The first sidewall 114L of the layer of molding material 114 additionally covers the second portion 104Lb of the first sidewall 104L of the transparent layer 104 in the second die 134.

The portion of the layer of molding material 114 covering the second sidewall 132R of the first die 132 forms a second sidewall 114R of the layer of molding material 114. The second sidewall 114R of the layer of molding material 114 covers the outer surface 112Rb of the second sidewall 112R of the solder mask 112 on the first die 132. The second sidewall 114R of the layer of molding material 114 additionally covers the second portion 104Rb of the second sidewall 104R of the transparent layer 104 in the first die 132.

The first sidewall 114L and the second sidewall 114R of the layer of molding material 114 may be approximately 200 micrometers in thickness.

The first region 114c of the layer of molding material 114 may be approximately 100 micrometers in thickness.

Singulation cavities 144 are also formed in the layer of molding material 114 closest to the first sidewall 132L of the first die 132 and in the layer of molding material 114 closest to the second sidewall 134R of the second die 134. A portion of the layer of molding material 114 remains on the first sidewall 132L of the first die 132, forming the first sidewall 114L of the layer of molding material 114 on the first die 132. A portion of the layer of molding material 114 remains on the second sidewall 134R of the second die 134, forming the second sidewall 114R of the layer of molding material 114 on the second die 134. A plurality of external portions 146 of the layer of molding material 114 remain attached to the second carrier layer 142 and are separated from the first sidewall 114L and second sidewall 114R of the layer of molding material 114 by singulation cavities 144 that extend along the first direction from the first surface 114a of the layer of molding material to the second carrier layer 142.

The second carrier layer 142 and the plurality of external portions 146 of the layer of molding material 114 are removed from the first die 132 and the second die 134. The embodiment in FIG. 1 depicts the final product of the method once the second carrier layer 142 and the plurality of external portions 146 of the layer of molding material 114 are removed.

The present disclosure is directed to a device that includes a substrate that includes a first surface opposite to a second surface and a plurality of sidewalls extending from the first surface to the second surface and a through silicon via extending from the second surface of the substrate to the first surface of the substrate. There is a transparent layer on the first surface of the substrate, the transparent layer including an exposed surface and a plurality of sidewalls that extend from the exposed surface to the first surface of the substrate. There is a solder mask on the second surface and each of the plurality of sidewalls of the substrate and coupled to a first portion of each of the plurality of sidewalls of the transparent layer and a layer of molding material covering the solder mask and a second portion of each of the plurality of sidewalls of the transparent layer. There are a first plurality of solder balls coupled to the substrate and a second plurality of solder balls coupled to each of the first plurality of solder balls.

The device includes each of the first plurality of solder balls with a flat surface. Each of the second plurality of solder balls is coupled to the flat surface of each of the first plurality of solder balls. A second through silicon via extending from the second surface of the substrate to the first surface of the substrate. A plurality of sensor elements coupled between the first surface of the substrate and the transparent layer, the plurality of sensor elements being between the first through silicon via and the second through silicon via. A dielectric layer is coupled to the second surface of the substrate and covering an internal surface of the first through silicon via. A redistribution layer partially covering the second surface of the substrate and covering an internal surface of the first through silicon via. A contact on the first surface of the substrate and coupled to the redistribution layer in the first through silicon via. An air gap in the first through silicon via between the solder mask and the contact on the first surface of the substrate. An outer surface of the layer of molding material is coplanar with the flat surface of each of the first plurality of solder balls.

The present disclosure is also directed to a device that includes a substrate that includes a first surface opposite to a second surface. A transparent layer coupled to the first surface of the substrate. A first plurality of solder balls coupled to the second surface of the substrate, each of the first plurality of solder balls having a flat surface and a layer of molding material coupled to the second surface of the substrate, the layer of molding material having an outer side that is coplanar with the flat surface of each of the first plurality of solder balls. A second plurality of solder balls, each of the second plurality of solder balls coupled to the layer of molding material and to one of the first plurality of solder balls. A solder mask is between the second surface of the substrate and the layer of molding material. The layer of molding material completely covers the solder mask and completely covers the plurality of sidewalls of the transparent layer. A through silicon via extending from the second surface of the substrate to the first surface of the substrate. An unfilled gap in the through silicon via between the solder mask and the first surface of the substrate.

The present disclosure is directed to a method that includes forming a first through silicon via from a first surface of a substrate layer to a second surface of a substrate layer, the second surface being opposite the first surface and forming a first opening completely through the substrate layer and partially through a transparent layer coupled to the second surface of the substrate layer. The method includes forming a solder mask on the first surface of the substrate layer and in the first opening and forming a second opening through the solder mask in the first opening, the second opening extending completely through the substrate layer and completely through the transparent layer. The method includes forming a redistribution layer on an internal surface of the first through silicon via and on the first surface of the substrate layer and forming a first plurality of solder balls coupled to the redistribution layer. The method includes forming a layer of molding material on the solder mask and in the second opening; forming a flat surface on each of the first plurality of solder balls; and forming a second plurality of solder balls, each of the second plurality of solder balls coupled to one of the first plurality of solder balls.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a substrate that includes a first surface opposite to a second surface and a plurality of sidewalls extending from the first surface to the second surface;
a through silicon via extending from the second surface of the substrate to the first surface of the substrate;
a transparent layer on the first surface of the substrate, the transparent layer including an exposed surface and a plurality of sidewalls that extend from the exposed surface to the first surface of the substrate;
a solder mask on the second surface and each of the plurality of sidewalls of the substrate and coupled to a first portion of each of the plurality of sidewalls of the transparent layer;
a layer of molding material covering the solder mask and a second portion of each of the plurality of sidewalls of the transparent layer;
a first plurality of solder balls coupled to the substrate; and
a second plurality of solder balls coupled to each of the first plurality of solder balls.

2. The device of claim 1, wherein each of the first plurality of solder balls has a flat surface.

3. The device of claim 2, wherein each of the second plurality of solder balls is coupled to the flat surface of each of the first plurality of solder balls.

4. The device of claim 1, wherein the transparent layer is glass.

5. The device of claim 1, comprising a second through silicon via extending from the second surface of the substrate to the first surface of the substrate.

6. The device of claim 5, comprising a plurality of sensor elements coupled between the first surface of the substrate and the transparent layer, the plurality of sensor elements being between the first through silicon via and the second through silicon via.

7. The device of claim 1, comprising a dielectric layer coupled to the second surface of the substrate and covering an internal surface of the first through silicon via.

8. The device of claim 1, comprising a redistribution layer partially covering the second surface of the substrate and covering an internal surface of the first through silicon via.

9. The device of claim 8, comprising a contact on the first surface of the substrate and coupled to the redistribution layer in the first through silicon via.

10. The device of claim 9, comprising an air gap in the first through silicon via between the solder mask and the contact on the first surface of the substrate.

11. The device of claim 2, wherein an outer surface of the layer of molding material is coplanar with the flat surface of each of the first plurality of solder balls.

12. A device, comprising:
a substrate that includes a first surface opposite to a second surface;
a transparent layer coupled to the first surface of the substrate;
a first plurality of solder balls coupled to the second surface of the substrate, each of the first plurality of solder balls having a flat surface;
a layer of molding material coupled to the second surface of the substrate, the layer of molding material having an outer side that is coplanar with the flat surface of each of the first plurality of solder balls; and
a second plurality of solder balls, each of the second plurality of solder balls coupled to the layer of molding material and to one of the first plurality of solder balls.

13. The device of claim 12, comprising a solder mask between the second surface of the substrate and the layer of molding material.

14. The device of claim 13, wherein the layer of molding material completely covers the solder mask and completely covers the plurality of sidewalls of the transparent layer.

15. The device of claim 12, comprising a through silicon via extending from the second surface of the substrate to the first surface of the substrate.

16. The device of claim 15, comprising an unfilled gap in the through silicon via between the solder mask and the first surface of the substrate.

17. A method, comprising:
forming a first through silicon via from a first surface of a substrate layer to a second surface of a substrate layer, the second surface being opposite the first surface;
forming a first opening completely through the substrate layer and partially through a transparent layer coupled to the second surface of the substrate layer;
forming a solder mask on the first surface of the substrate layer and in the first opening; and
forming a second opening through the solder mask in the first opening, the second opening extending completely through the substrate layer and completely through the transparent layer.

18. The method of claim 17, comprising forming a redistribution layer on an internal surface of the first through silicon via and on the first surface of the substrate layer.

19. The method of claim 18, comprising forming a first plurality of solder balls coupled to the redistribution layer.

20. The method of claim 19, comprising:
forming a layer of molding material on the solder mask and in the second opening;
forming a flat surface on each of the first plurality of solder balls; and
forming a second plurality of solder balls, each of the second plurality of solder balls coupled to one of the first plurality of solder balls.
